(19) United States
(12) Patent Application Publication
(10) Pub. No.: US 2026/0243641 A1
(43) Pub. Date: Aug. 20, 2026

(54) LIQUID-GAS PHASE-CHANGE LAUNCHING DEVICE, AND HYPERVELOCITY PENETRATION TEST DEVICE AND METHOD

(71) Applicant: Central South University, Changsha (CN)

(72) Inventors: Shujian YAO, Changsha (CN); Chengming SUN, Changsha (CN); Kai LIU, Changsha (CN); Eryong HOU, Changsha (CN); Zhaijun LU, Changsha (CN); Nan ZHAO, Changsha (CN)

(21) Appl. No.: 19/212,516

(22) Filed: May 19, 2025

(30) Foreign Application Priority Data
Aug. 5, 2024 (CN) 202411061355.1

(51) Int. Cl. G01N 3/30; G01P 3/38

(52) U.S. Cl. CPC G01N 3/30; G01P 3/38; G01N 2203/001; G01N 2203/0042; G01N 2203/0218

(57) ABSTRACT

A liquid-gas phase-change launching device includes an initial chamber, a connecting component, a launch tube and phase-change tubes. Two ends of the initial chamber are communicated with the connecting component and the launch tube, respectively. The connecting component is provided with through holes. The phase-change tubes are communicated with the initial chamber through the through holes. The initial chamber has a cavity inside. An end of the cavity near the through holes is larger than an end of the cavity near the launch tube in caliber. The cavity includes a first sub-cavity and a second sub-cavity. A first end of the first sub-cavity is communicated with the through holes. A second end of the first sub-cavity is communicated with a first end of the second sub-cavity. A second end of the second sub-cavity is communicated with the launch tube.

### CROSS-REFERENCE TO RELATED APPLICATIONS

This application claims the benefit of priority from Chinese Patent Application No. 202411061355.1, filed on Aug. 5, 2024. The content of the aforementioned application, including any intervening amendments made thereto, is incorporated herein by reference in its entirety.

### TECHNICAL FIELD

This application relates to projectile penetration test, and more particularly to a liquid-gas phase-change launching device, and a hypervelocity penetration test device and method.

### BACKGROUND

In the fields of protective engineering, composite materials, and weaponry, it is often necessary to perform penetration and ground impact tests at hypervelocity to investigate the damage and failure effects, as well as the penetration resistance capabilities, of materials such as rock, concrete, composite ceramics, naval steel plates and reactive armor steel plates. The penetration test is generally conducted as follows. (1) Selection of a suitable target: Based on the test requirements, representative targets are chosen, such as steel plates, concrete walls, etc. (2) Determination of test conditions, including ejecting velocity, range, and incident angle of the projectile, and the material and dimension of the target. (3) Test: The projectile is launched toward the target, and relevant test data are recorded according to the test objectives. (4) Result analysis: The related test data are analyzed.

Currently, light-gas guns, which utilizes compressed gas to propel objects at high speeds, are generally used for hypervelocity penetration tests. During the operation process, the stored compressed gas is released to generate a propelling force to accelerate the object. However, the large longitudinal length greatly limits the mobility and maneuverability of light-gas guns, making them unsuitable for outdoor testing scenarios. Additionally, some light-gas guns involve the use of dangerous gas, such as hydrogen. Furthermore, light-gas guns are costly, and have limited controllability and adjustability in terms of launching velocity.

Chinese Patent Application Publication No. 111288842A discloses a supercritical carbon dioxide gas gun, in which magnesium powder and carbon dioxide are reacted under heating conditions to produces magnesium oxide and carbon, accompanied by the release of a large amount of heat; and the generated heat is absorbed by the unreacted carbon dioxide, causing a rapid pressure rise to rupture the diaphragm to propel the projectile. This configuration can accelerate solid conical-head projectiles weighing approximately 1 kg to reach a tube-exit velocity of 200-600 m/s. However, this system is only suitable for the hypervelocity ejection of light projectiles weighing about 1 kg, and fails to achieve the hypervelocity penetration of heavy projectiles weighing around 20 kg.

The penetration test is susceptible to various factors, and thus the ejecting velocity of the projectile tends to vary. Therefore, a high-speed photographic velocity measurement device is required to measure the ejecting velocity during each launching operation, which not only increases the cost of the testing equipment, but also makes the testing process more cumbersome.

### SUMMARY

An object of the present disclosure is to provide a liquid-gas phase-change launching device to remedy the deficiency in the prior art that the existing gas guns struggle with poor mobility, high gas-related hazards, high costs, and great difficulty in controlling and adjusting launching speed, and fail to achieve the hypervelocity penetration of heavy projectiles weighing around 20 kg. Another object of the present disclosure is to provide a hypervelocity penetration test device and method.

To achieve the above objective, the present disclosure provides the following technical solutions.

A liquid-gas phase-change launching device, comprising:
an initial chamber;
a connecting component;
a launch tube; and
a plurality of phase-change tubes;
wherein a first end of the initial chamber is communicated with the connecting component; a second end of the initial chamber is communicated with the launch tube;
the connecting component is provided with a plurality of through holes; and the plurality of phase-change tubes are communicated with the initial chamber respectively through the plurality of through holes;
the initial chamber has a cavity inside; an end of the cavity near the plurality of through holes is larger than an end of the cavity near the launch tube in terms of caliber; the cavity comprises a first sub-cavity and a second sub-cavity; a first end of the first sub-cavity is communicated with the plurality of through holes; a second end of the first sub-cavity is communicated with a first end of the second sub-cavity; a second end of the second sub-cavity is communicated with the launch tube; the first sub-cavity has a truncated cone structure; and the second sub-cavity has a cylindrical structure; and
a length of the first sub-cavity is configured to be determined through steps of:
(S1) setting a first length L₀, and calculating a first energy loss ΔP₀ based on a Darcy-Weisbach equation when the length of the first sub-cavity is the first length L₀;
(S2) setting a second length

$${L}_{0}^{′} ,$$

and calculating a second energy loss

$$Δ {P}_{0}^{′}$$

based on the Darcy-Weisbach equation when the length of the first sub-cavity is the second length

$${L}_{0}^{′} ,$$

wherein

$${L}_{0}^{′} = ( 1 - S ) * {L}_{0} ,$$

and S represents a first step size and is a positive number less than 1;
(S3) determining whether

$$\vert Δ {P}_{0}^{′} - Δ {P}_{0} \vert$$

is less than a tolerance; if yes, determining the second length

$${L}_{0}^{′}$$

as the length of the first sub-cavity; otherwise, proceeding to step (S4); and

$$( S 4 ) if Δ {P}_{0}^{′} > Δ {P}_{0} ,$$

setting s third length

$${L}_{0}^{″} ;$$

calculating a third energy loss

$$Δ {P}_{0}^{″}$$

based on the Darcy-Weisbach equation when the length of the first sub-cavity is the third length

$${L}_{0}^{″} ,$$

wherein

$${L}_{0}^{″} = ( 1 - {S}^{′} ) * {L}_{0}^{′} ; {S}^{′}$$

represents a second step size and is a positive number less than 1; replacing a value of the second length

$${L}_{0}^{′}$$

with a value of the third length

$${L}_{0}^{″} ,$$

and replacing a value of the second energy loss

$$Δ {P}_{0}^{′}$$

with a value of the third energy loss

$$Δ {P}_{0}^{″} ;$$

and returning to step (S3); and

$$if Δ {P}_{0}^{′} \leq Δ {P}_{0} ,$$

setting a fourth length

$${L}_{0}^{′′′} ;$$

calculating a fourth energy loss

$$Δ {P}_{0}^{′′′}$$

based on the Darcy-Weisbach equation when the length of the first sub-cavity is the fourth length

$${L}_{0}^{′′′}$$

wherein

$${L}_{0}^{′′′} = ( 1 + {S}^{″} ) * {L}_{0}^{′} ; {S}^{″}$$

represents a third step size and is a positive number less than 1; replacing a value of the second length

$${L}_{0}^{′}$$

with a value of the fourth length

$${L}_{0}^{′′′} ,$$

and replacing a value of the second energy loss

$$Δ {P}_{0}^{′}$$

with a value of the fourth energy loss

$$Δ {P}_{0}^{′″} ;$$

and returning to step (S3).

In an embodiment, an end of the launch tube near the initial chamber is boltedly provided with a projectile.

A hypervelocity penetration test system, further comprising:
the liquid-gas phase-change launching device described above;
a controller;
a pressure sensor; and
a photographic velocity measurement device;
wherein the pressure sensor and the photographic velocity measurement device are communicatively connected with the controller;
the pressure sensor is provided inside the initial chamber; and
the photographic velocity measurement device is provided at a launch end of the liquid-gas phase-change launching device, and is configured to obtain a measured velocity of a projectile.

In an embodiment, the hypervelocity penetration test system further comprising:
a filter;
wherein the filter is communicatively connected with the pressure sensor and the controller; and
the filter is configured to filter a pressure signal collected by the pressure sensor, and send a filtered pressure signal to the controller.

A hypervelocity penetration test method using the hypervelocity penetration test system, comprising:
(A) based on a velocity level of a hypervelocity penetration test, determining the number of the plurality of phase-change tubes and a launching interval of adjacent two of the plurality of phase-change tubes;
(B) launching the projectile toward a target, and obtaining a pressure signal P(t) collected by the pressure sensor after the projectile is launched;
(C) calculating an estimated velocity of the projectile at any moment through the following equations:

$${F}_{s} = \frac{{\int }_{0}^{{t}_{1}} ( \frac{( P ( t ) - {P}_{atm} ) \cdot A}{m} ) dt - {v}^{′} ( {t}_{1} )}{{t}_{1}} ;$$

$$a ( t ) = \frac{( P ( t ) - {P}_{atm} ) \cdot A}{m} - {F}_{s} ; and$$

$$v ( t ) = {\int }_{0}^{t} a ( t ) dt ;$$

wherein a(t) represents an estimated acceleration of the projectile at moment t; P(t) represents an air pressure in the initial chamber at the moment t; v(t) represents an estimated velocity of the projectile at the moment t; Pₐₜₘ represents an atmospheric pressure; A represents a cross-sectional area at a tail end of the projectile; m represents a weight of the projectile; Fₛ represents a friction coefficient; v′(t₁) represents a measured velocity of the projectile at moment t₁; t₁ represents a moment when the projectile exits the launch tube; and a moment when the projectile starts to move is defined as moment 0;
(D) substituting the moment t₁ into the above equations to obtain an estimated tube-exit velocity v(t₁) of the projectile; and
(E) obtaining a range, a penetration depth and an impact angle of the projectile; evaluating a penetration capability and a destructive power of the projectile based on the estimated tube-exit velocity, the range, the penetration depth and the impact angle of the projectile.

In an embodiment, after step (B) and before step (C), comprising:
filtering the pressure signal.

In an embodiment, step (C) further comprises:
calculating an estimated travel distance of the projectile from the moment 0 to the moment t based on the estimated velocity of the projectile at the moment t; and
calculating the range of the projectile based on the estimated travel distance of the projectile and the moment t.

This application has at least the following technical effects or advantages.
(1) The device provided herein has characteristics of high mobility, low gas hazard and lower cost. It not only enables hypervelocity penetration for heavy projectiles weighing around 20 kg, but also allows the control of the tube-exit velocity of the projectile by installing phase-change with tubes in various numbers.
(2) By merely measuring the air pressure in the initial chamber, the estimated tube-exit velocity of the projectile can be obtained using the described method. This eliminates the need for a high-speed photographic velocity measurement device for each test, thereby reducing the cost of the testing equipment and simplifying the test procedure.
(3) By filtering the pressure signal to remove noise or unwanted frequency components, smoother and more accurate curves can be obtained, which enhances the accuracy of the estimation results.

### BRIEF DESCRIPTION OF THE DRAWINGS

FIG. 1 shows the installation of the liquid-gas phase-change launching device according to an embodiment of the present disclosure;

FIG. 2 is a structural diagram (exploded view) of the liquid-gas phase-change launching device according to an embodiment of the present disclosure;

FIG. 3 is a structural diagram of the initial chamber according to an embodiment of the present disclosure;

FIG. 4 is a structural diagram of the projectile according to an embodiment of the present disclosure;

FIG. 5 is a structural diagram of the projectile mounting plate according to an embodiment of the present disclosure;

FIG. 6 is a structural diagram of the shear bolt according to an embodiment of the present disclosure;

FIG. 7 shows the comparison between the projectile accelerations with the shear bolt and without the shear bolt according to an embodiment of the present disclosure;

FIG. 8 is a structural diagram of the high-speed photographic velocity measurement device (Scheme 1) according to an embodiment of the present disclosure;

FIG. 9 is a structural diagram of the high-speed photographic velocity measurement device (Scheme 2) according to an embodiment of the present disclosure;

FIG. 10 is a schematic diagram of the pressure-time curve after filtering according to an embodiment of the present disclosure;

FIG. 11 is a schematic diagram of the estimated acceleration-time curve of the projectile according to an embodiment of the present disclosure;

FIG. 12 is a schematic diagram of the estimated velocity-time curve of the projectile according to an embodiment of the present disclosure; and

FIG. 13 is a schematic diagram of the estimated range-time curve of the projectile according to an embodiment of the present disclosure.

### DETAILED DESCRIPTION OF EMBODIMENTS

For a better understanding of the present disclosure, a more comprehensive description of the present disclosure will be provided with reference to the accompanying drawings.

### Embodiment 1

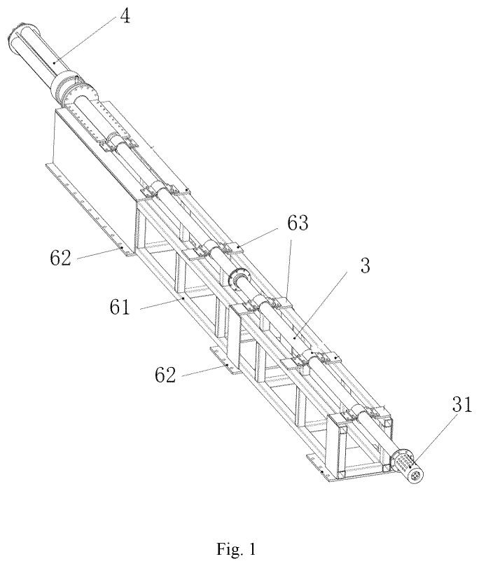

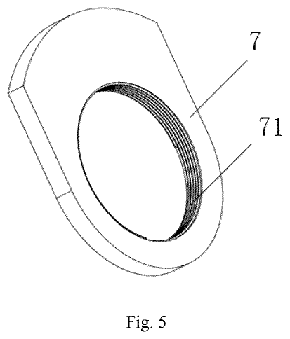

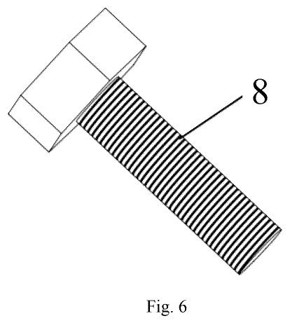

As shown in FIGS. 1-6, a liquid-gas phase-change launching device includes an initial chamber, a connecting component, a launch tube; and a plurality of phase-change tubes.

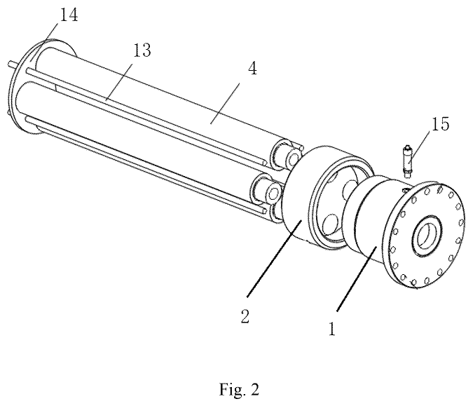

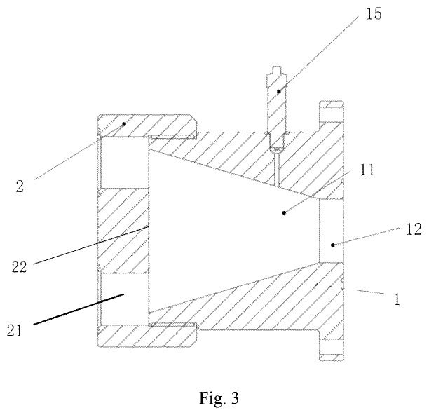

As shown in FIGS. 2-3, the initial chamber 1 is provided with a first sub-cavity 11 and a second sub-cavity 12. One end of the first sub-cavity 11 is connected to a connecting component 2, and the other end of the first sub-cavity 11 is communicated with one end of the second sub-cavity 12. The other end of the second sub-cavity 12 is connected to a launch tube 3. The connecting component 2 is provided with a plurality of through-holes 21 (in this embodiment, there are four through-holes 21), which allow a varying number of phase-change tubes 4 to be installed on the ends of the through-holes 21 away from the first sub-cavity 11, depending on the application needs. Through-holes 21 that are not fitted with phase-change tubes 4 can be sealed with plugs. This configuration enables the phase-change tubes 4, the through-holes 21 on the connecting component 2, the first sub-cavity 11, the second sub-cavity 12 and the launch tube 3 to be sequentially connected. When liquid carbon dioxide is filled into the phase-change tubes 4, a high-pressure carbon dioxide gas generated by the liquid-gas phase transition sequentially passes through the through-holes 21 on the connecting component 2, the first sub-cavity 11 and the second sub-cavity 12 into the launch tube 3, thereby propelling the projectile 5 within the launch tube 3 outward.

To increase the projectile's launch velocity, the first sub-cavity 11 has a circular truncated cone structure, while the second sub-cavity 12 has a cylindrical structure. The end of the first sub-cavity 11 which connects to the through-holes 21 has a larger diameter than the end that connects to the second sub-cavity 12.

The diameter of the second sub-cavity 12 is determined as follows: the diameter D₂ of the second sub-cavity 12 is designed to match the size of the launch tube, which is primarily based on the size of the projectile to be launched. The dimensions are approximately the same as those of the projectile, both to facilitate loading and to minimize the gap between the projectile and the launch tube, thereby preventing CO₂ leakage and ensuring efficient gas utilization.

The first sub-cavity 11 is determined as follows: the diameter of the end of the first sub-cavity 11 that is connected to the through holes 21 is determined based on the installation of four phase-change tubes 4 and is a fixed value. Therefore, the diameters D1 and D2 at both ends of the first sub-cavity 11 are fixed, and only the length L of the first sub-cavity 11 needs to be designed. Based on the known diameters at both ends of the first sub-cavity 11 and the physical properties of carbon dioxide (temperature, density, etc.), the length that minimizes energy loss can be designed through the following steps.

The energy loss ΔP is calculated using the Darcy-Weisbach equation, with an iterative approach. The iterative approach is expressed as:

$$Δ P = \sum \frac{f ρ {L}_{i} {v}_{avg , i}^{2}}{2 {D}_{avg , i}} ;$$

In the above formula, f is the friction factor; Lᵢ is the length of each pipe segment (Li=L/n, i=1, 2, 3, . . . , n); D_{avg,i} is the average diameter of each pipe segment (D_{avg,i}=(Dᵢ+Dᵢ₊₁)/2), ρ is the fluid density; V_{avg,i} is the average flow velocity of each pipe segment (V_{avg,i}=Q/((π*D_{avg,i}²)/4)).

An initial pipe length Lₒ is set, which is the first length. The energy loss □P₀ of the first sub-cavity is calculated based on the Darcy-Weisbach equation when the length of the first sub-cavity is the first length (with Lᵢ=L₀/n, i=1,2,3, . . . , n).

A second length is set

$${L}_{0}^{′} , {L}_{0}^{′} = ( 1 - S ) * {L}_{0} ,$$

where S is a small positive value less than 1 that controls the degree of the adjustment. The energy loss

$${VP}_{0}^{′}$$

of the first sub-cavity is calculated based on the Darcy-Weisbach equation when the length of the first sub-cavity is the second length.

$$( with ( {L}_{i} = {L}_{0}^{′} / n , i = 1 , 2 , 3 , … , n ) ) .$$

Convergence is then checked through whether

$$\vert ▯ {P}_{0}^{′} - ▯ {P}_{0} \vert$$

is less than a tolerance. The tolerance is can be set based on design requirements, such as 0.1, 0.01, or 0.0001.

If convergence is not reached, the length of the first sub-cavity is adjusted based on the energy loss.

$$If ▯ {P}_{0}^{′} > ▯ {P}_{0} ,$$

the length of the first sub-cavity is decreased. Setting

$${L}_{0}^{″} = ( 1 - {S}^{′} ) * {L}_{0}^{′} {S}^{′}$$

represents a second step size and is a positive number less than 1; and the energy loss

$$▯ {P}_{0}^{″}$$

of the first sun-cavity is calculated through the Darcy-Weisbach equation when the length of the first sub-cavity is

$${L}_{0}^{″} .$$

$$If ▯ {P}_{0}^{′} < ▯ {P}_{0} ,$$

the length of the first sub-cavity is increased. Setting

$${L}_{0}^{′″} = ( 1 + {S}^{″} ) * {L}_{0}^{′} ; {S}^{″}$$

represents a third step size and is a positive number less than 1, and the energy loss

$$▯ {P}_{0}^{″}$$

of the first sub-cavity is calculated through the Darcy-Weisbach equation when the length of the first sub-cavity is

$${L}_{0}^{″} .$$

Setting

$$▯ {P}_{0}^{″} = ▯ {P}_{0}^{′} ,$$

increment the iteration count, and repeat the process until convergence is achieved or the maximum number of iterations is reached. The final length obtained from this iterative process is the length of the first sub-cavity with minimum energy loss.

Specifically, the initial chamber 1 is threadedly connected to the connecting component 2, and the phase-change tubes 4 are also threadedly installed in the through holes 21 of the connecting component 2. Preferably, the assembly can be further reinforced using tie rods 13 and a mounting plate 14. After the phase-change tubes 4 are installed in the through holes 21, the mounting plate 14 is configured to press against the rear ends of the phase-change tubes 4, and both ends of the tie rods 13 are fixedly connected to the mounting plate 14 and the connecting component 2, respectively.

As shown in FIG. 1, the liquid-gas phase-change launching device can be mounted on a launching rack. The launching rack includes a U-shaped square tube truss body 61, a fixing plate 62, and clamps 63. The U-shaped square tube truss body 61 is fixed to the ground through the fixing plate 62, and the liquid-gas phase-change launching device is mounted onto the U-shaped square tube truss body 61 via the clamps 63. Preferably, a muzzle brake 31 is also installed at the end of the launch tube 3 away from the initial chamber 1.

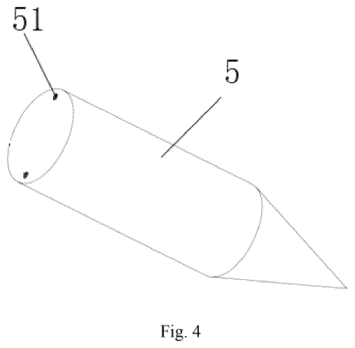

As shown in FIGS. 4-6, at the end of the launch tube 3 near the initial chamber 1, two projectile mounting plates 7 are radially mounted opposite each other. These projectile mounting plates 7 are symmetrically installed on both sides inside the launch tube 3. Each projectile mounting plate 7 has holes 71, and the tail of the projectile 5 is provided with threaded holes 51 at positions corresponding to the projectile mounting plates 7. Shear bolts 8 pass through the holes 71 and are threadedly connected to the threaded holes 51, thereby fixing the projectile 5 inside the launch tube 3.

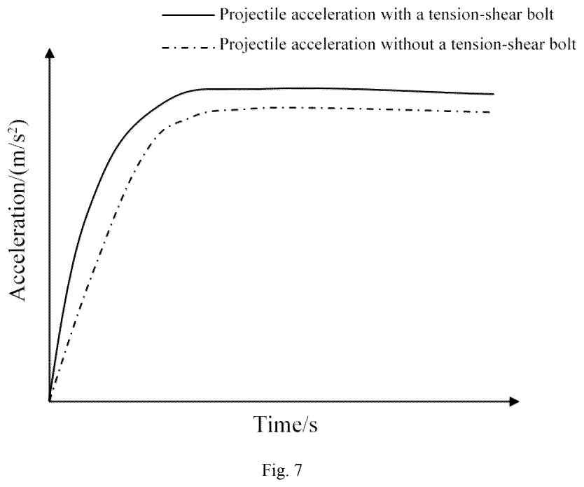

The reason for using shear bolts 8 to fix the projectile 5 is to utilize the kinetic energy from the gas expansion to provide sufficient initial momentum and thrust to the projectile 5 to be launched. Once activated, the liquid carbon dioxide in the phase-change tubes 4 rapidly expands, forming a high-pressure gas stream. By fixing the projectile 5 in the front section of the launch tube 3, the high-pressure gas can fully apply to the projectile 5, giving it sufficient acceleration. Without the shear bolts 8, the projectile 5 would begin to move as soon as the pressure generated by the carbon dioxide exceeded the frictional force between the projectile 5 and the launch tube 3. However, in that case, the acceleration of the projectile 5 might not be high enough, leading to an insufficient exit velocity of the projectile 5. A comparison between the accelerations of the projectiles with and without shear bolts is shown in FIG. 7.

The applicable speed range of the liquid-gas phase-change launching device provided herein is for projectiles traveling below 1000 m/s. The term “hypervelocity” in this application refers to projectile speeds between 100 m/s and 1000 m/s. To achieve penetration test speeds of 200 m/s, 300 m/s, and 400 m/s; and the number of phase-change tubes is configured as shown in Table 1.

200 m/s level penetration test: 1 phase-change tube is used.

300 m/s level penetration test: 3 phase-change tubes are used. The phase-change activation moments of liquid carbon dioxide are 0 ms, 6 ms and 12 ms.

400 m/s level penetration test: 4 phase-change tubes are used. The phase-change activation moments of liquid carbon dioxide are 0 ms, 5 ms, 8 ms and 13 ms.

TABLE 1
the parameter of the phase-change tube

| | | the number of | time |
|---|---|---|---|
| Serial | | the phase- | sequence |
| No. | speed level | change tubes | (ms) |
| 1 | 200 m/s level | 1 | — |
| 2 | 300 m/s level | 3 | 0 |
| | | | 6 |
| | | | 12 |
| 3 | 400 m/s level | 4 | 0 |
| | | | 5 |
| | | | 8 |
| | | | 13 |

### Embodiment 2

A hypervelocity penetration test system includes the liquid-gas phase-change launching device described above, as well as a controller, a pressure sensor 15, a filter, and a high-speed photographic velocity measurement device. The pressure sensor is installed inside the initial chamber. Specifically, as shown in FIG. 3, the initial chamber 1 is equipped with a pressure sensor 15. The pressure sensor 15 includes a data acquisition end and a data transmission end. The data acquisition end is located inside the first sub-cavity 11, and the data transmission end is located outside the initial chamber 1. The data transmission end is in communication with the controller. The filter is in communication with the pressure sensor and the controller. The filter is configured to filter the pressure signals collected by the pressure sensor before sending them to the controller. The filter may be implemented as an exponentially weighted moving average filter. The high-speed photographic velocity measurement device is positioned at the launch end of the liquid-gas phase-change launching device and is communicatively connected to the controller for acquiring the measured speed of the projectile.

The high-speed photographic velocity measurement device can be adopted through the following schemes.

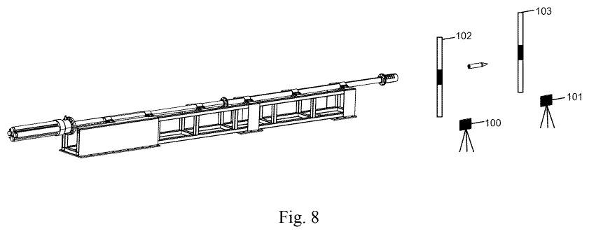

Scheme 1 is described as follows, as shown in FIG. 8. The high-speed photographic velocity measurement device includes a first high-speed camera 100, a second high-speed camera 101, a first marker rod 102, and a second marker rod 103. The first marker rod 102 is located 0.1 meters from the muzzle of the launch tube. Both the first and second marker rods are positioned on the same side of the launch tube. The distance between the first marker rod 102 and the second marker rod 103 is 0.835 meters. The direction formed by the first marker rod 102 and the second marker rod 103 is aligned with the launch direction of the launch tube. The shooting direction of the first high-speed camera 100 and the launch direction of the barrel are perpendicular and intersect at the first marker rod 102. The distance between the first high-speed camera 100 and the first marker rod 102 is 1 meter. The shooting direction of the second high-speed camera 101 and the launch direction of the launch tube are perpendicular and intersect at the second marker rod 103, with the distance between the second high-speed camera 101 and the second marker rod 103 also being 1 meter. The first high-speed camera 100 records the moment the projectile reaches the first marker rod 102, while the second high-speed camera 101 records when the projectile reaches the second marker rod 103. The projectile's exit velocity is then calculated using the moment difference between the two recordings. The velocity of the projectile is equal to the distance between the two marker rods divided by the moment it takes the projectile to travel between the two marker rods.

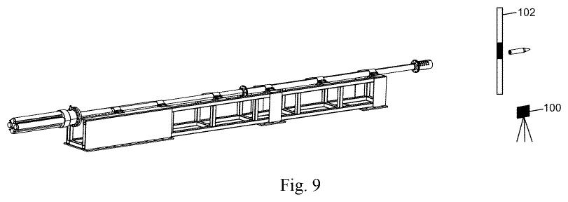

Scheme 2 is described as follows, as shown in FIG. 9. The high-speed photographic velocity measurement device includes the first high-speed camera 100 and the first marker rod 102. The first marker rod 102 is positioned 0.1 meters from the muzzle of the launch tube. The shooting direction of the first high-speed camera 100 and the launch direction are perpendicular and intersect at the first marker rod 102. The distance between the first camera and the marker rod is 1 meter. The first high-speed camera 100 records the moments when the projectile head passes the first marker rod 102 and when the projectile tail passes the first marker rod 102. The velocity of the projectile is then calculated by dividing the projectile length by the moment it takes the projectile to pass the marker rod.

### Embodiment 3

A hypervelocity penetration test method using the hypervelocity penetration test system includes the following steps.
(A) Based on a velocity level of a hypervelocity penetration test, the number of the plurality of phase-change tubes and a launching interval of adjacent two of the plurality of phase-change tubes are determined.
(B) The projectile is launched toward a target, and a pressure signal collected by the pressure sensor after the projectile is launched is obtained. Filtering is applied to the pressure signal; Specifically, in this embodiment, an exponentially weighted moving average filter is used, expressed as:

$$y ( n ) = {α}^{*} x ( n ) + {( 1 - α )}^{*} y ( n - 1 ) ;$$

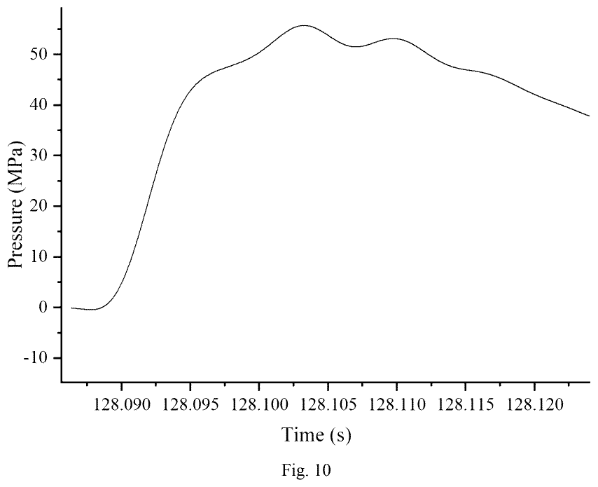

In the above formula, y(n) represents filtered data points; x(n) represents original data points; α is the smoothing constant (with a value range from 0 to 1); n is the index of the data point. FIG. 10 shows the pressure-time curve of the initial chamber after filtering.
(C) An estimated velocity of the projectile at any moment is calculated through equations:

$${F}_{s} = \frac{{\int }_{0}^{{t}_{1}} ( \frac{( P ( t ) - {P}_{atm} ) \cdot A}{m} ) dt - {v}^{′} ( {t}_{1} )}{{t}_{1}} ;$$

$$a ( t ) = \frac{( P ( t ) - {P}_{atm} ) \cdot A}{m} - {F}_{s} ;$$

$$v ( t ) = {\int }_{0}^{t} a ( t ) dt ;$$

In the above formula, a(t) represents an estimated acceleration of the projectile at a moment t; P(t) represents an air pressure in the initial chamber at the moment t; v(t) represents an estimated velocity of the projectile at the moment t; Pₐₜₘ represents an atmospheric pressure; A represents a cross-sectional area at a tail end of the projectile; m represents a weight of the projectile; Fₛ represents a friction coefficient; v′(t₁) represents a measured velocity of the projectile at a moment t₁; t₁ represents a moment when the projectile exits the launch tube; and a moment when the projectile starts to move is defined as zero.

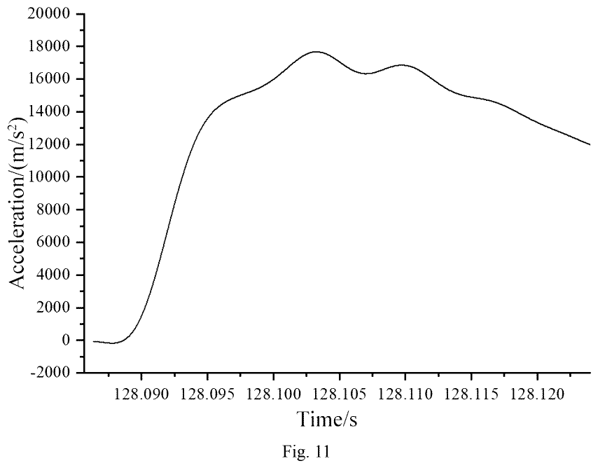

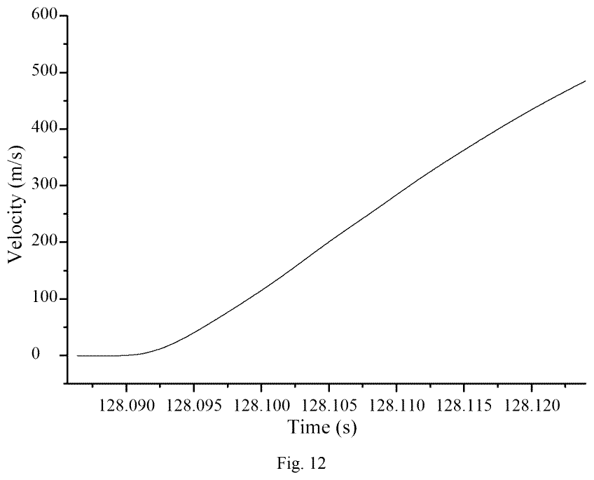

Since the friction coefficient Fₛ is related to factors such as the material type and surface roughness, if the frictional force is neglected when the coefficient is not yet determined, the estimated tube-exit velocity of the projectile will be higher than the actual value measured by the hypersonic speed measurement system. Therefore, when launching the same type of projectile, a penetration test should be conducted. The actual tube-exit velocity of the projectile can be measured using the high-speed imaging velocity measurement device, and then the friction coefficient Fₛ can be determined by back-calculating using the above formulas. In subsequent hypersonic penetration tests, the pressure-time curve of the initial chamber can be obtained through measurement. Based on this curve, the estimated velocity-time curve of the projectile can be derived using the aforementioned formulas. The estimated tube-exit velocity of the projectile can then be obtained by identifying the estimated velocity corresponding to the moment when the projectile exits the launch tube on the velocity-time curve. FIG. 11 shows the estimated acceleration-time curve of the projectile, and FIG. 12 shows the estimated velocity-time curve.
(D) The moment t₁ when the projectile exits the launch tube is substituted into the equations to obtain an estimated tube-exit velocity v(t₁) of the projectile.
(E) A range, a penetration depth and an impact angle of the projectile are obtained; a penetration capability and a destructive power of the projectile are evaluated based on the estimated tube-exit velocity, the range, the penetration depth and the impact angle of the projectile.

The range of projectile can be obtained using existing methods. Preferably, the estimated travel distance of the projectile at any given moment can also be calculated based on its estimated velocity at that moment, thereby determining the range. The calculation formula is as follows:

$$s ( t ) = {\int }_{0}^{t} v ( t ) dt ;$$

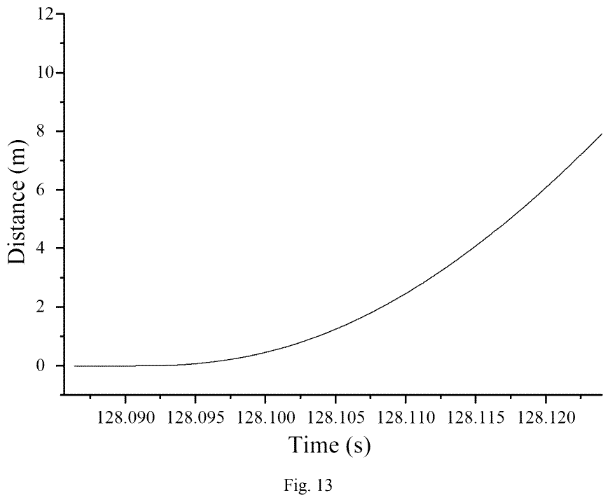

In the above formula, s(t) represents the estimated range of the projectile in moment t. FIG. 13 shows the estimated travel distance-time curve of the projectile.

The damage mode and energy absorption of the penetrated object can be obtained through the target impact depth of the projectile. Different damage modes lead to different energy absorption mechanisms, such as shear failure, ductile tearing, etc. By investigating the damage mode of the penetrated object, one can guide engineering protection design and provide valuable references for virtual simulations. Energy absorption calculation of the penetrated object is extremely important in engineering fields. In areas like structural protection, high-speed rail, and aerospace, energy absorption must be considered. Different impact angles result in different damage modes in the penetrated material. For example, oblique impact tests on various structures are very important because many structures exhibit anisotropic mechanical characteristics.

By analyzing the projectile's estimated tube-exit velocity, range, impact depth, and impact angle, its penetration capability and destructive power can be assessed. These key parameters help evaluate the resistance of different materials to projectile penetration, providing data support for material selection and improvement. They also verify whether the projectile design meets the expected penetration performance, ensuring design effectiveness. Furthermore, analyzing the projectile's penetration performance under real battlefield conditions offers a basis for tactical planning and application. This promotes the development of projectile design and manufacturing technologies, improving their performance and reliability. The test results also play a key role in formulating or revising relevant technical standards and specifications, ensuring standardization and compliance within the industry.

In the present specification, numerous specific details are described. However, it should be understood that embodiments of the present disclosure can be practiced without these specific details. In some instances, well-known methods, structures, and techniques are not described in detail so as not to obscure the understanding of this specification.

Similarly, it should be understood that, in order to streamline this disclosure and aid in the understanding of one or more aspects of the disclosure, the features of the present disclosure are sometimes grouped together in a single embodiment, figure, or description thereof. However, this disclosure should not be interpreted as reflecting an intention that the claimed disclosure requires more features than those expressly recited in each claim. Rather, as the claims reflect, aspects of the disclosure lie in less than all features of a single disclosed embodiment. Thus, the claims following the detailed description are hereby expressly incorporated into the detailed description, where each claim stands as a separate embodiment of the disclosure.

It should be understood by those skilled in the art that modules, units, or groups of devices disclosed in the examples herein may be arranged within the described devices, or alternatively may be located in one or more different devices from those in the example. The modules in the above-mentioned examples may be combined into a single module or further divided into multiple submodules.

It will also be understood by those skilled in the art that the modules in the devices of the embodiments can be adaptively modified and deployed in one or more different devices from the described embodiments. Modules, units, or groups in the embodiments can be combined into a single module, unit, or group, and may further be divided into multiple sub-modules, sub-units, or subgroups. Except where such features and/or processes or units are mutually exclusive, any combination of all features disclosed in this specification (including the accompanying claims, abstract, and drawings), as well as any combination of processes or units of any method or device so disclosed, can be adopted. Unless otherwise expressly stated, each feature disclosed in this specification (including the accompanying claims, abstract, and drawings) may be replaced with alternative features providing the same, equivalent, or similar purpose.

Additionally, those skilled in the art will appreciate that although some embodiments described herein include certain features of other embodiments rather than others, combinations of features of different embodiments are meant to be within the scope of the disclosure and form different embodiments. For example, any one of the claimed embodiments in the claims that follow may be used in any combination.

Moreover, some embodiments described herein are described as being implementable by a processor of a computer system or by a combination of other devices performing the described functions. Therefore, a processor having the necessary instructions for implementing the method or method elements forms a device for implementing the method or method elements. The elements of the apparatus embodiments described herein are examples of devices for performing the functions executed by the elements for the purpose of implementing the disclosure.

The various techniques described herein may be implemented in hardware or software, or a combination thereof. Thus, the methods and apparatuses of the present disclosure, or certain aspects or portions thereof, may take the form of program code (i.e., instructions) embodied in a tangible medium such as a floppy disk, CD-ROM, hard disk drive, or any other machine-readable storage medium, which, when loaded into and executed by a machine such as a computer, cause the machine to become an apparatus for practicing the disclosure.

When program code is executed on a programmable computer, the computing device generally includes a processor, processor-readable storage media (including volatile and non-volatile memory and/or storage elements), at least one input device, and at least one output device. The memory is configured to store the program code, and the processor is configured to execute the method of the disclosure according to the instructions in the program code stored in the memory.

By way of example and not limitation, computer-readable media include computer storage media and communication media. Computer storage media store information such as computer-readable instructions, data structures, program modules, or other data. Communication media typically embody computer-readable instructions, data structures, program modules, or other data in a modulated data signal such as a carrier wave or other transmission mechanism, and include any information delivery media. Any combination of the above may also be included within the scope of computer-readable media.

As used herein, unless otherwise specified, ordinal terms such as “first,” “second,” “third,” and so on are used merely to distinguish different instances of similar objects and are not intended to imply a particular order in time, space, sequence, or any other dimension.

Although the disclosure has been described in terms of a limited number of embodiments, those skilled in the art, in light of the disclosure, will recognize that other embodiments are possible within the scope of the disclosure as described. Furthermore, it should be noted that the language used in this specification has been principally chosen for readability and teaching purposes and is not intended to limit or define the subject matter of the disclosure. Therefore, many modifications and variations will be apparent to those of ordinary skill in the art without departing from the scope and spirit of the appended claims. The disclosure is intended to be illustrative, not limiting, and the scope of the disclosure is defined by the appended claims.

Finally, it is noted that common knowledge well recognized by those skilled in the art is not elaborated herein. The foregoing is merely a specific embodiment of the disclosure and is not intended to limit the disclosure. Any modifications, equivalent substitutions, improvements, etc., made within the spirit and principles of the disclosure should be included within the protection scope of the disclosure.

What is claimed is:

1. A liquid-gas phase-change launching device, comprising:
an initial chamber;
a connecting component;
a launch tube; and
a plurality of phase-change tubes;
wherein a first end of the initial chamber is communicated with the connecting component; a second end of the initial chamber is communicated with the launch tube; the connecting component is provided with a plurality of through holes; and the plurality of phase-change tubes are communicated with the initial chamber respectively through the plurality of through holes;
the initial chamber has a cavity inside; an end of the cavity near the plurality of through holes is larger than an end of the cavity near the launch tube in terms of caliber; the cavity comprises a first sub-cavity and a second sub-cavity; a first end of the first sub-cavity is communicated with the plurality of through holes; a second end of the first sub-cavity is communicated with a first end of the second sub-cavity; a second end of the second sub-cavity is communicated with the launch tube; the first sub-cavity has a truncated cone structure; and the second sub-cavity has a cylindrical structure; and
a length of the first sub-cavity is configured to be determined through steps of:
(S1) setting a first length L₀, and calculating a first energy loss ΔP₀ based on a Darcy-Weisbach equation when the length of the first sub-cavity is the first length L₀;
(S2) setting a second length
$${L}_{0}^{′} ,$$
and calculating a second energy loss
$${Δ P}_{0}^{′}$$
based on the Darcy-Weisbach equation when the length of the first sub-cavity is the second length
$${L}_{0}^{′} ,$$
wherein
$${L}_{0}^{′} = ( 1 - S ) * {L}_{0} ,$$
and S represents a first step size and is a positive number less than 1;
(S3) determining whether
$$\vert {Δ P}_{0}^{′} - {Δ P}_{0} \vert$$
is less than a tolerance; if yes, determining the second length
$${L}_{0}^{′}$$
is the length of the first sub-cavity; otherwise, proceeding to step (S4); and
$$( S4 ) if {Δ P}_{0}^{′} > {Δ P}_{0} ,$$
setting a third length
$${L}_{0}^{″} ;$$
calculating a third energy loss
$${Δ P}_{0}^{″}$$
based on the Darcy-Weisbach equation when the length of the first sub-cavity is the third length
$${L}_{0}^{″} ,$$
wherein
$${L}_{0}^{″} = ( 1 - {S}^{′} ) * {L}_{0}^{′} ; {S}^{′}$$
represents a second step size and is a positive number less than 1; replacing a value of the second length
$${L}_{0}^{′}$$
with a value of the third length
$${L}_{0}^{″} ,$$
and replacing a value of the second energy loss
$$Δ {P}_{0}^{′}$$
with a value of the third energy loss
$$Δ {P}_{0}^{″} ;$$
and returning to step (S3); and
$$if Δ {P}_{0}^{′} \leq Δ {P}_{0} ,$$
setting a fourth length
$${L}_{0}^{″′} ;$$
calculating a fourth energy loss
$$Δ {P}_{0}^{″′}$$
based on the Darcy-Weisbach equation when the length of the first sub-cavity is the fourth length
$${L}_{0}^{″′} ,$$
wherein
$${L}_{0}^{″′} = ( 1 + {S}^{″} ) * {L}_{0}^{′} ;$$
S″ represents a third step size and is a positive number less than 1; replacing a value of the second length
$${L}_{0}^{′}$$
with a value or the fourth length
$${L}_{0}^{″′} ,$$
and replacing a value of the second energy loss
$$Δ {P}_{0}^{′}$$
with a value of the fourth energy loss
$$Δ {P}_{0}^{″′} ;$$
and returning to step (33).

2. The liquid-gas phase-change launching device of claim 1, wherein an end of the launch tube near the initial chamber is boltedly provided with a projectile.

3. A hypervelocity penetration test system, comprising:
the liquid-gas phase-change launching device of claim 1 or 2;
a controller;
a pressure sensor; and
a photographic velocity measurement device;
wherein the pressure sensor and the photographic velocity measurement device are communicatively connected with the controller;
the pressure sensor is provided inside the initial chamber; and
the photographic velocity measurement device is provided at a launch end of the liquid-gas phase-change launching device, and is configured to obtain a measured velocity of a projectile.

4. The hypervelocity penetration test system of claim 3, further comprising:
a filter;
wherein the filter is communicatively connected with the pressure sensor and the controller; and
the filter is configured to filter a pressure signal collected by the pressure sensor, and send a filtered pressure signal to the controller.

5. A hypervelocity penetration test method using the hypervelocity penetration test system of claim 3 or 4, comprising:
(A) based on a velocity level of a hypervelocity penetration test, determining the number of the plurality of phase-change tubes and a launching interval of adjacent two of the plurality of phase-change tubes;
(B) launching the projectile toward a target, and obtaining a pressure signal P(t) collected by the pressure sensor after the projectile is launched;
(C) calculating an estimated velocity of the projectile at any moment through the following equations:
$${F}_{s} = \frac{{\int }_{0}^{{t}_{1}} ( \frac{( P ( t ) - {P}_{atm} ) \cdot A}{m} ) dt - {v}^{′} ( {t}_{1} )}{{t}_{1}}$$
$$;$$
$$a ( t ) = \frac{( P ( t ) - {P}_{a t m} ) \cdot A}{m} - {F}_{s} ; and$$
$$v ( t ) = {\int }_{0}^{t} a ( t ) dt ;$$
wherein a(t) represents an estimated acceleration of the projectile at moment t; P(t) represents an air pressure in the initial chamber at the moment t; v(t) represents an estimated velocity of the projectile at the moment t; Pₐₜₘ represents an atmospheric pressure; A represents a cross-sectional area at a tail end of the projectile; m represents a weight of the projectile; Fₛ represents a friction coefficient; v′(t₁) represents a measured velocity of the projectile at moment t₁; t₁ represents a moment when the projectile exits the launch tube; and a moment when the projectile starts to move is defined as moment 0;
(D) substituting the moment t₁ into the above equations to obtain an estimated tube-exit velocity v(t₁) of the projectile; and
(E) obtaining a range, a penetration depth and an impact angle of the projectile; evaluating a penetration capability and a destructive power of the projectile based on the estimated tube-exit velocity, the range, the penetration depth and the impact angle of the projectile.

6. The hypervelocity penetration test method of claim 5, after step (B) and before step (C), further comprising:
filtering the pressure signal.

7. The hypervelocity penetration test method of claim 6, wherein step (C) further comprises:
calculating an estimated travel distance of the projectile from the moment 0 to the moment t based on the estimated velocity of the projectile at the moment t; and
calculating the range of the projectile based on the estimated travel distance of the projectile and the moment t.
